(19) United States
(12) Patent Application Publication
(10) Pub. No.: US 2008/0113483 A1
(43) Pub. Date: May 15, 2008

(54) Methods of etching a pattern layer to form staggered heights therein and intermediate semiconductor device structures

(75) Inventor: David H. Wells, Boise, ID (US)

Correspondence Address: TRASK BRITT, P.C./ MICRON TECHNOLOGY, P.O. BOX 2550, SALT LAKE CITY, UT, 84110, US

(73) Assignee: Micron Technology, Inc.

(21) Appl. No.: 11/599,914

(22) Filed: Nov. 15, 2006

(51) Int. Cl. H01L 21/76

(52) U.S. Cl. 438/424; 257/E21.54

(57) ABSTRACT

A method of forming staggered heights in a pattern layer of an intermediate semiconductor device structure. The method comprises providing an intermediate semiconductor device structure comprising a pattern layer and a first mask layer, forming first openings in the pattern layer, forming spacers adjacent to etched portions of the pattern layer to reduce a width of the first openings, etching the pattern layer to increase a depth of the first openings, and forming second openings in the pattern layer. A method of forming staggered heights in the pattern layer that includes spacers formed on multiple mask layers is also disclosed. Intermediate semiconductor device structures are also disclosed.

### FIELD OF THE INVENTION

Embodiments of the invention relate to fabricating an intermediate semiconductor device structure. Specifically, embodiments of the present invention relate to forming staggered heights in a pattern layer of the intermediate semiconductor device structure using a single photolithography act and a spacer etch process and to intermediate semiconductor device structures.

### BACKGROUND OF THE INVENTION

Integrated circuit (“IC”) designers desire to increase the level of integration or density of features within an IC by reducing the size of the individual features and by reducing the separation distance between neighboring features on a semiconductor substrate. The continual reduction in feature sizes places ever-greater demands on techniques used to form the features, such as photolithography. These features are typically defined by openings in, and spaced from each other by, a material, such as an insulator or conductor. The distance between identical points in neighboring features is referred to in the industry as “pitch.” For instance, the pitch is typically measured as the center-to-center distance between the features. As a result, pitch is approximately equal to the sum of the width of a feature and of the width of the space separating that feature from a neighboring feature. The width of the feature is also referred to as the critical dimension or minimum feature size (“F”) of the line. Because the width of the space adjacent to the feature is typically equal to the width of the feature, the pitch of the feature is typically two times the feature size (2F).

To reduce feature sizes and pitch, pitch doubling techniques have been developed. U.S. Pat. No. 5,328,810 discloses a method of pitch doubling using spacers or mandrels to form evenly spaced trenches in a semiconductor substrate. The trenches have equal depths. An expendable layer is formed on the semiconductor substrate and patterned, forming strips having a width of F. The strips are etched, producing mandrel strips having a reduced width of F/2. A partially expendable stringer layer is conformally deposited over the mandrel strips and etched to form stringer strips having a thickness of F/2 on sidewalls of the mandrel strips. The mandrel strips are etched while the stringer strips remain on the semiconductor substrate. The stringer strips function as a mask to etch trenches having a width of F/2 in the semiconductor substrate.

While the pitch in the above-mentioned patent is actually halved, such a reduction in pitch is referred to in the industry as “pitch doubling” or “pitch multiplication.” In other words, “multiplication” of pitch by a certain factor involves reducing the pitch by that factor. This conventional terminology is retained herein.

Pitch doubling has also been used to produce trenches having different depths in the semiconductor substrate. U.S. Patent Application No. 20060046407 discloses a dynamic random access memory (“DRAM”) cell having U-shaped transistors. The disclosure of U.S. Patent Application No. 20060046407 is incorporated by reference herein in its entirety. U-shaped protrusions are formed by three sets of crossing trenches. To form the transistors, a first photomask is used to etch a first set of trenches in the semiconductor substrate. The first set of trenches is filled with a dielectric material. A second photomask is used to etch gaps between the first trenches and a second set of trenches is etched in the semiconductor substrate at the gaps. The second set of trenches is then filled with a dielectric material. The first and second sets of trenches are parallel to one another and the trenches in the second set of trenches are deeper than those in the first set of trenches. To form the first and second sets of trenches, two photolithography acts (deposit, pattern, etch, and fill acts) are used, which adds cost and complexity to the fabrication process. A third set of trenches is subsequently formed in the semiconductor substrate. The third set of trenches is orthogonal to the first and second sets of trenches.

The first, second, and third sets of trenches 100, 102, 104 as described above form U-shaped transistors, as shown in FIGS. 1 and 2 of the drawings. FIG. 1 illustrates a top view of device 106 and FIG. 2 is a perspective view of pillars 108 of device 106. The device 106 includes an array of pillars 108, the first set of trenches 100, the second set of trenches 102, and the third (or wordline) set of trenches 104. As illustrated in FIG. 1, the first set of trenches 100 are filled, such as with an oxide (labeled as “O” in FIG. 1). Pairs of pillars 108′ form protrusions 110 of vertical transistors. Each vertical transistor protrusion 110 includes two pillars 108, which are separated by the filled, first set of trenches 100 and connected by a channel base segment 114 that extends beneath the first set of trenches 100. The vertical transistor protrusions 110 are separated from one another in the y-direction by the filled, second set of trenches 102. Wordline spacers or wordlines 116 are separated from one another by the filled, third set of trenches 104.

Each U-shaped pillar construction has two U-shaped side surfaces facing a trench from the third set of trenches 104 (or wordline trench), forming a two-sided surround gate transistor. Each U-shaped pillar pair 108′ includes two back-to-back U-shaped transistor flow paths having a common source, drain, and gate. Because the back-to-back transistor flow paths in each U-shaped pillar pair 108′ share the source, drain, and gate, the back-to-back transistor flow paths in each U-shaped pillar pair do not operate independently of each other. The back-to-back transistor flow paths in each U-shaped pillar pair 108′ form redundant flow paths of one transistor protrusion 110. When the transistors are active, the current stays in left side and right side surfaces of the U-shaped transistor protrusion 110. The left side and right side surfaces of the U-shaped transistor protrusion 110 are defined by the trenches in the third set of trenches 104. The current for each path stays in one plane. The current does not turn the corners of the U-shaped transistor protrusion 110.

U.S. Patent Application No. 20060043455 discloses forming shallow trench isolation (“STI”) trenches having multiple trench depths and trench widths. Trenches having a first depth, but different widths, are first formed in a semiconductor substrate. The trenches are filled with a dielectric material, which is then selectively removed from wider trenches. The wider trenches are then deepened by etching the semiconductor substrate.

U.S. Patent Application No. 20060166437 discloses forming trenches in a memory array portion of a memory device and in a periphery of the memory device. The trenches initially have the same depth. A hard mask layer is formed over the trenches in the memory array portion, protecting these trenches from subsequent etching, while the trenches in the periphery are further etched, increasing their depth.

### BRIEF DESCRIPTION OF THE SEVERAL VIEWS OF THE DRAWINGS

While the specification concludes with claims particularly pointing out and distinctly claiming that which is regarded as the present invention, the advantages of the embodiments of the invention may be more readily ascertained from the following description of embodiments of the invention when read in conjunction with the accompanying drawings in which:

FIGS. 1 and 2 show U-shaped transistors formed according to the prior art;

FIGS. 3A-11E show an embodiment of forming staggered heights in a pattern layer of an intermediate semiconductor device structure according to the present invention; and

FIGS. 12A-24F show an embodiment of forming staggered heights in a pattern layer of an intermediate semiconductor device structure according to the present invention.

### DETAILED DESCRIPTION OF THE INVENTION

Embodiments of methods of forming staggered heights in a pattern layer of an intermediate semiconductor device structure are disclosed. The staggered, or multiple, heights are formed using a single photolithography act and a spacer etch process. The staggered heights produce trenches or lines of different depths in the pattern layer. Features including, but not limited to, isolation regions, gates, or three-dimensional transistors may be formed in the trenches. Intermediate semiconductor device structures formed by these methods are also disclosed.

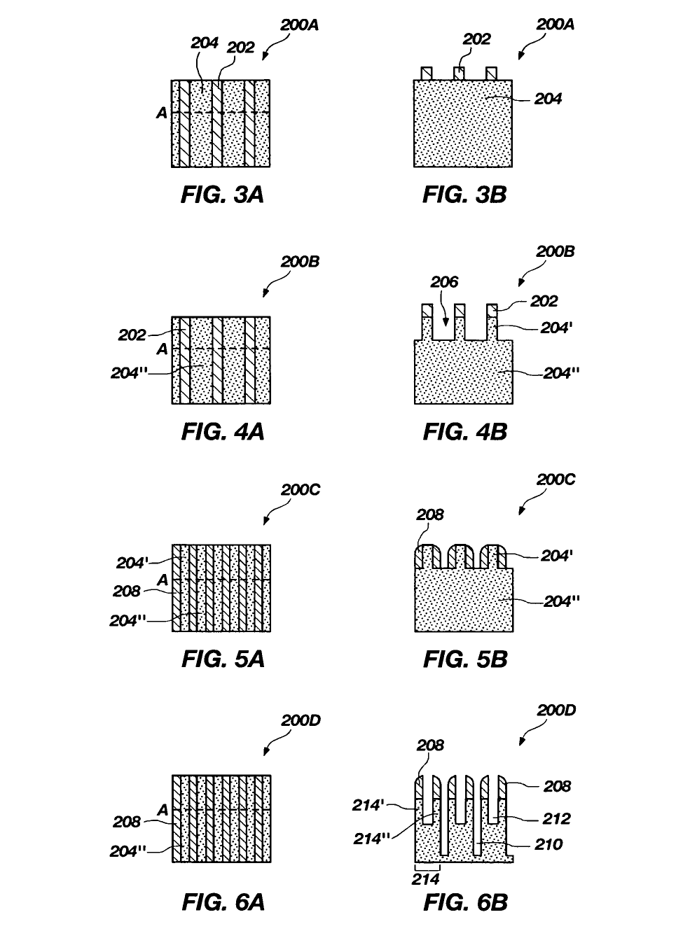

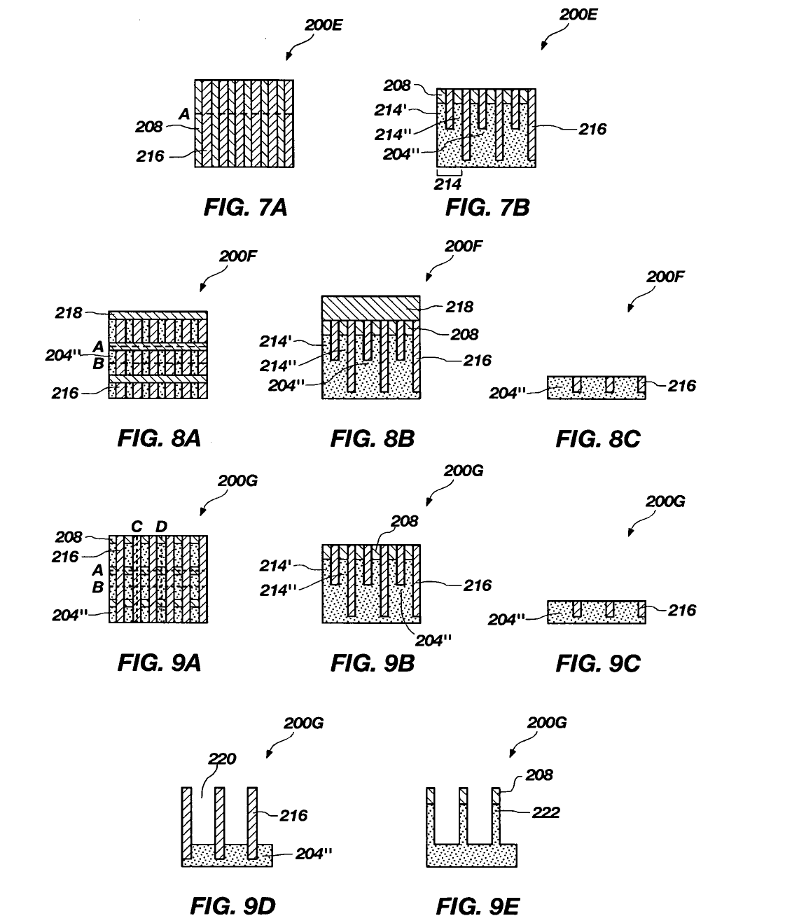

As described in detail herein and as illustrated in FIGS. 3A-11E, a first mask layer is formed on the pattern layer and patterned. The first mask layer and spacers formed by the spacer etch process function as masks during subsequent etching so that the staggered heights are formed in the pattern layer. A first etch may be used to form openings in the pattern layer, which form a portion of a first set of trenches. A second etch is used to increase the depth of the openings in the pattern layer, forming the first set of trenches, and to form a second set of trenches.

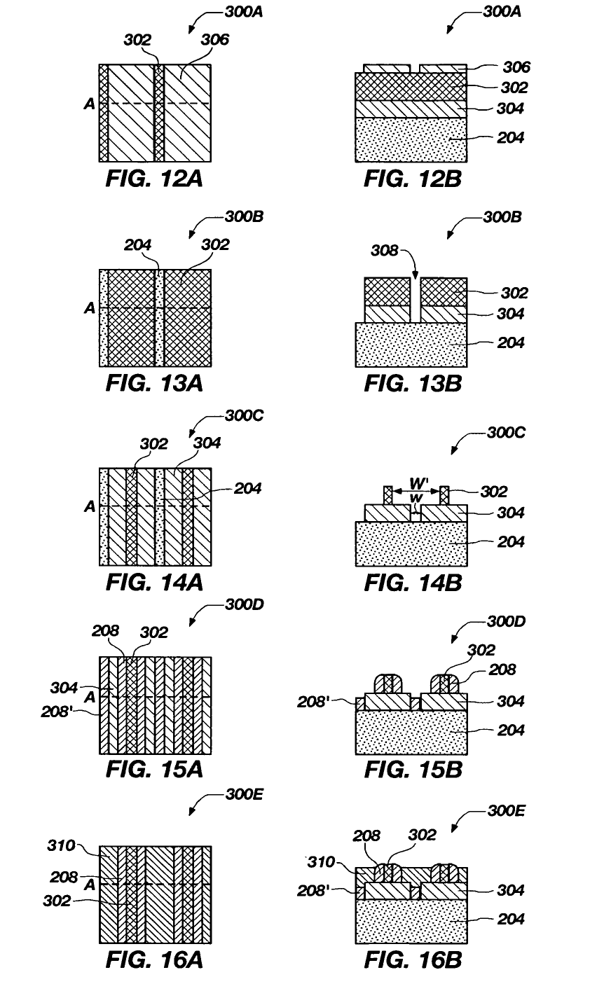

As described in detail herein and as illustrated in FIGS. 12A-24F, multiple mask layers are formed on the pattern layer and patterned. The mask layers and spacers formed by the spacer etch process function as masks during subsequent etching so that the staggered heights are formed in the pattern layer. A first etch may be used to form openings in the pattern layer, which form a portion of a fourth set of trenches. A second etch is used to increase the depth of the openings in the pattern layer, forming the fourth set of trenches, and to form a fifth set of trenches.

The following description provides specific details, such as material types, etch chemistries, and processing conditions, in order to provide a thorough description of embodiments of the present invention. However, a person of ordinary skill in the art will understand that the embodiments of the present invention may be practiced without employing these specific details. Indeed, the embodiments of the present invention may be practiced in conjunction with conventional fabrication techniques and etching techniques employed in the industry. In addition, the description provided below does not form a complete process flow for manufacturing a semiconductor device. The intermediate semiconductor device structures described below do not form a complete semiconductor device. Only those process steps and structures necessary to understand the embodiments of the present invention are described in detail below. Additional acts to form the complete semiconductor device from the intermediate semiconductor device structures may be performed by conventional fabrication techniques.

The material layers described herein may be formed by any suitable deposition technique including, but not limited to, spin coating, blanket coating, chemical vapor deposition (“CVD”), atomic layer deposition (“ALD”), plasma enhanced ALD, or physical vapor deposition (“PVD”). Depending on the specific material to be used, the deposition technique may be selected by a person of ordinary skill in the art.

The methods described herein may be used to form intermediate semiconductor device structures of memory devices, such as dynamic random access memory DRAM, RAD, F in FET, saddle FETs, nanowires, three-dimensional transistors, or other three-dimensional structures. For the sake of example only, the methods herein describe fabricating intermediate semiconductor device structures of memory devices, such as a DRAM memory device or a RAD memory device. However, the methods may also be used in other situations where staggered heights or elevations in a pattern layer are desired. The memory device may be used in wireless devices, personal computers, or other electronic devices, without limitation. While the methods described herein are illustrated in reference to specific DRAM device layouts, the methods may be used to form DRAM devices having other layouts as long as the isolation regions are substantially parallel to locations where gates will ultimately be formed.

As shown in FIGS. 3A-4B, the intermediate semiconductor device structure 200A, 200B may include a pattern layer and a first mask layer. The pattern layer may be formed from a material that is capable of being anisotropically etched. For instance, the pattern layer may include, but is not limited to, a semiconductor substrate or an oxide material. As used herein, the term “semiconductor substrate” refers to a conventional silicon substrate or other bulk substrate having a layer of semiconductive material. As used herein, the term “bulk substrate” includes not only silicon wafers, but also silicon-on-insulator (“SOI”) substrates, silicon-on-sapphire (“SOS”) substrates, epitaxial layers of silicon on a base semiconductor foundation, and other semiconductor, optoelectronics, or biotechnology materials, such as silicon-germanium, germanium, gallium arsenide, gallium nitride, or indium phosphide. In one embodiment, the pattern layer is formed from silicon, such as a silicon semiconductor substrate.

The first mask layer may be formed from a patternable material that is selectively etchable relative to the pattern layer and to other exposed layers of the intermediate semiconductor device structure 200A, 200B. As used herein, a material is “selectively etchable” when the material exhibits an etch rate of at least approximately two times greater than that of another material exposed to the same etch chemistry. Ideally, such a material has an etch rate of at least approximately ten times greater than that of another material exposed to the same etch chemistry. The material of the first mask layer may include, but is not limited to, a photoresist, amorphous carbon (or transparent carbon), tetraethylorthosilicate (“TEOS”), polycrystalline silicon (“polysilicon”), silicon nitride (“Si₃N₄”), silicon oxynitride (“SiO₃N₄”), silicon carbide (“SiC”), or any other suitable material. If a photoresist material is used, the photoresist may be a 248 nm photoresist, a 193 nm photoresist, a 365 nm (I-line) photoresist, or a 436 nm (G-line) photoresist, depending on the size of features to be formed on the intermediate semiconductor device structure. The photoresist material may be deposited on the pattern layer and patterned by conventional, photolithographic techniques. Photoresists and photolithographic techniques are well known in the art and, therefore, selecting, depositing, and patterning the photoresist material are not discussed in detail herein. FIGS. 3A and 3B show the intermediate semiconductor device structure 200A having portions of the first mask layer 202 remaining over the pattern layer 204. The first mask layer 202 protects underlying portions of the pattern layer 204. While FIGS. 3A and 3B illustrate a 1 F line etched on a 4 F pitch, other layouts may be used. FIG. 3A is a top view of the intermediate semiconductor device structure 200A and FIG. 3B is a cross-section of the intermediate semiconductor device structure 200A along the dashed line labeled A.

The pattern of the first mask layer 202 may be transferred into the pattern layer 204, as shown in FIGS. 4A and 4B. FIG. 4A is a top view of the intermediate semiconductor device structure 200B and FIG. 4B is a cross-section of the intermediate semiconductor device structure 200B along the dashed line labeled A. The intermediate semiconductor device structure 200B shown in FIGS. 4A and 4B includes the first mask layer 202, etched portions of the pattern layer 204′, unetched portions of the pattern layer 204″, and first openings 206. The pattern layer 204 may be etched by ion milling, reactive ion etching, or chemical etching. The pattern layer 204 may be selectively etchable relative to the first mask layer 202. For instance, if the pattern layer 204 is formed from silicon, the pattern layer 204 may be anisotropically etched using HBr/Cl₂ or a fluorocarbon plasma etch. To etch a desired depth into the pattern layer 204 formed from silicon, the etch time may be controlled. For instance, the silicon may be exposed to the appropriate etch chemistry for an amount of time sufficient to achieve the desired depth in the silicon. This depth may correspond to a desired height of spacers to be formed on sidewalls of the etched portions of the pattern layer 204′.

The first mask layer 202 remaining over the etched portions of the pattern layer 204′ may be removed by conventional techniques. For instance, the first mask layer 202 may be removed by the etch used to transfer the pattern of the first mask layer 202 to the pattern layer 204 or by a separate etch. For instance, if a photoresist material or amorphous carbon is used as the first mask layer 202, the photoresist or the amorphous carbon may be removed using an oxygen-based plasma, such as an O₂/Cl₂ plasma, an O₂/HBr plasma, or an O₂/SO₂/N₂ plasma. A spacer layer may be formed over the exposed surfaces of the intermediate semiconductor device structure 200B. The spacer layer may be conformally deposited over the etched portions of the pattern layer 204′ and the unetched portions of the pattern layer 204″ by conventional techniques. The spacer layer may be formed to a thickness that is approximately equal to the desired thickness of spacers to be formed therefrom. The etched portions of the pattern layer 204′ may be selectively etchable relative to the material used as the spacer layer. For the sake of example only, the spacer layer may be formed from silicon Si₃N₄ or silicon oxide (“SiOₓ”). The spacer layer may be formed by ALD. The spacer layer may be anisotropically etched, removing the spacer material from substantially horizontal surfaces while leaving the spacer material on substantially vertical surfaces. As such, the substantially horizontal surfaces of the etched portions of the pattern layer 204′ and the substantially horizontal surfaces of the unetched portions of the pattern layer 204″ may be exposed. If the spacer layer is formed from SiOₓ, the anisotropic etch may be a plasma etch, such as a CF₄-containing plasma, a C₂F₆-containing plasma, a C₄F₈-containing plasma, a CHF₃-containing plasma, a CH₂F₂-containing plasma, or mixtures thereof. If the spacer layer is formed from silicon nitride, the anisotropic etch may be a CHF₃/O₂/He plasma or a C₄F₈/CO/Ar plasma. The spacers 208 produced by the etch may be present on substantially vertical sidewalls of the etched portions of the pattern layer 204′, as shown in FIGS. 5A and 5B. FIG. 5A is a top view of the intermediate semiconductor device structure 200C and FIG. 5B is a cross-section of the intermediate semiconductor device structure 200C along the dashed line labeled A. The spacers 208 extend longitudinally along both sides of the etched portions of the pattern layer 204′. The two spacers 208 positioned along the sidewalls of each etched portion of the pattern layer 204′ form a pair of spacers 208. The spacers 208 may reduce the size of the first openings 206 between the etched portions of the pattern layer 204′. The height of the spacers 208 may correspond to a portion of the depth of the first set of trenches ultimately to be formed in the pattern layer 204. The width of the spacers 208 may correspond to the desired width of features ultimately to be formed on the intermediate semiconductor device structure 200. For instance, the width of the spacers 208 may be 1 F. A portion of the first set of trenches 210 (shown in FIG. 6B), having a width of 1 F, may be formed in the pattern layer 204.

A second etch may be performed to increase the depth of the first openings 206, forming the first set of trenches 210, and to form the second set of trenches 212, as shown in FIG. 6B. FIG. 6A is a top view of the intermediate semiconductor device structure 200D and FIG. 6B is a cross-section of the intermediate semiconductor device structure 200D along the dashed line labeled A. The substantially horizontal surfaces of the etched portions of the pattern layer 204′ and of the unetched portions of the pattern layer 204″ may be anisotropically etched using one of the etch chemistries previously discussed. By controlling the etch time, a desired amount of the etched portions of the pattern layer 204′ and of the unetched portions of the pattern layer 204″ may be removed. The trenches in the second set of trenches 212 may be shallower than the trenches in the first set of trenches 210 because the portions of the pattern layer 204 in which the second set of trenches 212 are ultimately formed are protected by the first mask layer 202 during the first etch of the pattern layer 204. The trenches of the first set of trenches 210 may have a depth within a range of from approximately 1500 Å to approximately 5000 Å, such as from approximately 2000 Å to approximately 3500 Å. In one embodiment, the depth of the trenches of the first set of trenches 210 ranges from approximately 2200 Å to approximately 2300 Å. The trenches in the second set of trenches 212 may have a depth within a range of from approximately 300 Å to approximately 4500 Å, such as from approximately 500 Å to approximately 1500 Å. In one embodiment, the depth of the trenches of the second set of trenches 212 ranges from approximately 750 Å to approximately 850 Å.

The intermediate semiconductor device structure 200D may include pairs of pillars 214 formed from the pattern layer 204. Each trench of the first (deeper) set of trenches 210 may separate one pair of pillars 214 from the next pair of pillars 214. Each trench of the second (shallower) set of trenches 212 may separate a first pillar 214′ in each pair of pillars 214 from a second pillar 214″ in each pair of pillars 214. As described below, the first and second sets of trenches 210, 212 may be subsequently filled with a dielectric material. The first set of trenches 210, the second set of trenches 212, and the pillars 214′, 214″ extend substantially longitudinally in the horizontal direction of the intermediate semiconductor device structure 200D.

By using a single photolithography act in combination with a spacer etch process, trenches 210, 212 having multiple depths may be formed in the pattern layer 204. Different features may subsequently be formed in the trenches of the first set of trenches 210 and in the trenches of the second set of trenches 212. For the sake of example only, and as described in more detail below, isolation regions may be formed in the trenches of the first set of trenches 210 and transistors may be formed in the trenches of the second set of trenches 212. Since only a single photolithography act is used, fewer acts may be utilized to form the intermediate semiconductor device structure 200D having multiple heights or depths in the pattern layer 204.

A liner (not shown) may, optionally, be deposited before filling the first and second sets of trenches 210, 212. The liner may be formed from conventional materials, such as an oxide or a nitride, and by conventional techniques. A first fill material 216, such as a dielectric material, may be deposited in the first and second sets of trenches 210, 212 and over the spacers 208. The first and second sets of trenches 210, 212 maybe filled substantially simultaneously. The first fill material 216 may be blanket deposited and densified, as known in the art. The first fill material 216 may be a silicon dioxide-based material, such as a spin-on-dielectric (“SOD”), silicon dioxide, TEOS, or a high density plasma (“HDP”) oxide. The first fill material 216 may be planarized, such as by chemical mechanical polishing (“CMP”), to remove portions of the first fill material 216 extending above the spacers 208. As such, top surfaces of the spacers 208 may be exposed, as shown in FIG. 7A and 7B. FIG. 7A is a top view of the intermediate semiconductor device structure 200E and FIG. 7B is a cross-section of the intermediate semiconductor device structure 200E along the dashed line labeled A.

As shown in FIGS. 8A-8C, a second mask layer 218 may be formed over the intermediate semiconductor device structure 200E shown in FIGS. 7A and 7B. FIG. 8A is a top view of the intermediate semiconductor device structure 200F, FIG. 8B is a cross-section of the intermediate semiconductor device structure 200F along the dashed line labeled A, and FIG. 8C is a cross-section of the intermediate semiconductor device structure 200F along the dashed line labeled B. The second mask layer 218 may be formed from one of the materials described above for the first mask layer 202, such as photoresist. The second mask layer 218 may be formed and patterned, as known in the art, and the pattern transferred to the pattern layer 204 to form a third set of trenches 220, as shown in FIGS. 9A-9E. FIG. 9A is a top view of the intermediate semiconductor device structure 200G, FIG. 9B is a cross-section of the intermediate semiconductor device structure 200G along the dashed line labeled A, FIG. 9C is a cross-section of the intermediate semiconductor device structure 200G along the dashed line labeled B, FIG. 9D is a cross-section of the intermediate semiconductor device structure 200G along the dashed line labeled C, and FIG. 9E is a cross-section of the intermediate semiconductor device structure 200G along the dashed line labeled D. For the sake of example only, the third set of trenches 220 may be wordline trenches. The pattern may be extended into the pattern layer 204 through the first fill material 216 in the first and second sets of trenches 210, 212, using a dry etch that etches the materials used in these layers at substantially the same rate. The third set of trenches 220 may extend substantially laterally in the horizontal plane of the intermediate semiconductor device structure 200G. As such, the third set of trenches 220 may be oriented substantially perpendicular or orthogonal to the first and second sets of trenches 210, 212. The trenches in the third set of trenches 220 may be shallower than the trenches in the first set of trenches 210 to enable a transistor gate electrode to be formed along sidewalls of the trenches of the third set of trenches 220. However, the trenches of the third set of trenches 220 may be deeper than the trenches of the second set of trenches 212 to enable the trenches of the second set of trenches 212 to provide isolation between closely spaced transistors when the wordline is enabled. The trenches of the third set of trenches 220 may have a depth within a range of from approximately 500 Å to approximately 5000 Å, such as from approximately 1400 Å to approximately 1800 Å. Third pillars 222, formed from the pattern layer 204 may be formed between the trenches of the third set of trenches 220. The third pillars 222 may be separated from one another by the first fill material 216 in the trenches of the third set of trenches 220.

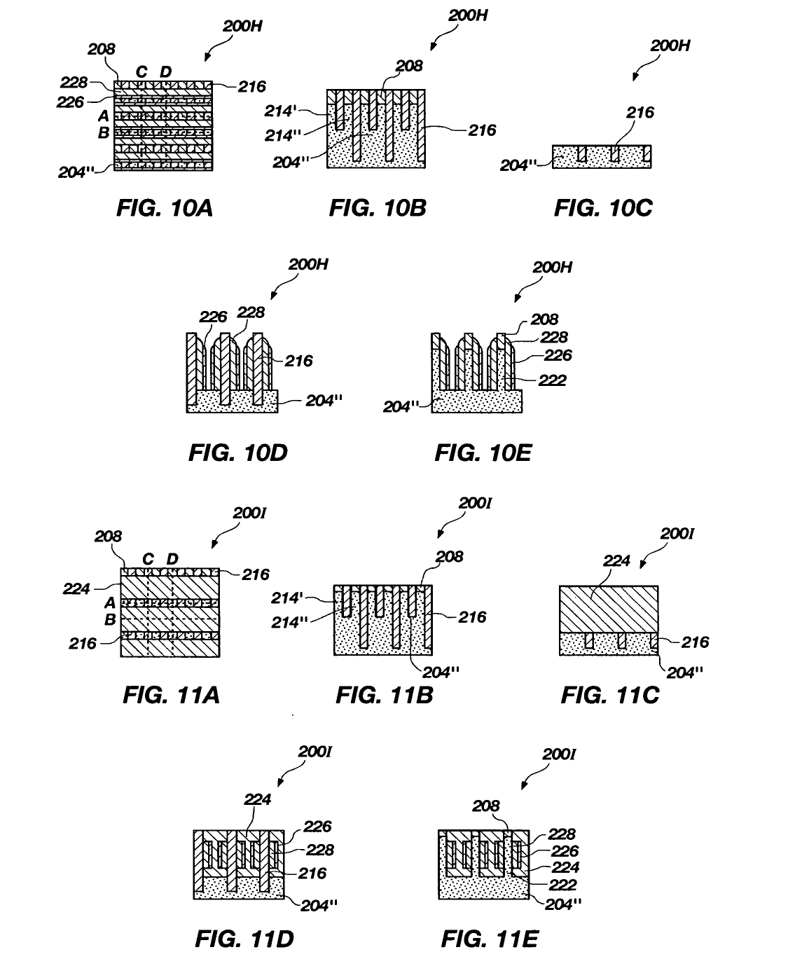

The second mask layer 218 may be removed by conventional techniques. A dielectric material 226 and a gate layer 228 may be deposited in the trenches of the third set of trenches 220, as shown in FIGS. 10A-10E. FIG. 10A is a top view of the intermediate semiconductor device structure 200H, FIG. 10B is a cross-section of the intermediate semiconductor device structure 200H along the dashed line labeled A, FIG. 10C is a cross-section of the intermediate semiconductor device structure 200H along the dashed line labeled B, FIG. 10D is a cross-section of the intermediate semiconductor device structure 200H along the dashed line labeled C, and FIG. 10E is a cross-section of the intermediate semiconductor device structure 200H along the dashed line labeled D. The dielectric material 226 may be silicon dioxide, such as a gate oxide. If the pattern layer 204 is silicon, the dielectric material 226 may be applied by wet or dry oxidation of the silicon followed by etching through a mask, or by dielectric deposition techniques. The gate layer 228 may be titanium nitride (“TiN”) or doped polysilicon. The gate layer 228 may be spacer etched to leave a contiguous layer on the sidewalls of the trenches of the third set of trenches 220. The remainder of the third set of trenches 220 may be filled with a second fill material 224, such as SOD or TEOS. The second fill material 224 may be planarized, providing the intermediate semiconductor device structure 200I shown in FIGS. 11A-11E. FIG. 11A is a top view of the intermediate semiconductor device structure 200I, FIG. 11B is a cross-section of the intermediate semiconductor device structure 200I along the dashed line labeled A, FIG. 11C is a cross-section of the intermediate semiconductor device structure 200I along the dashed line labeled B, FIG. 11D is a cross-section of the intermediate semiconductor device structure 200I along the dashed line labeled C, and FIG. 11E is a cross-section of the intermediate semiconductor device structure 200I along the dashed line labeled D.

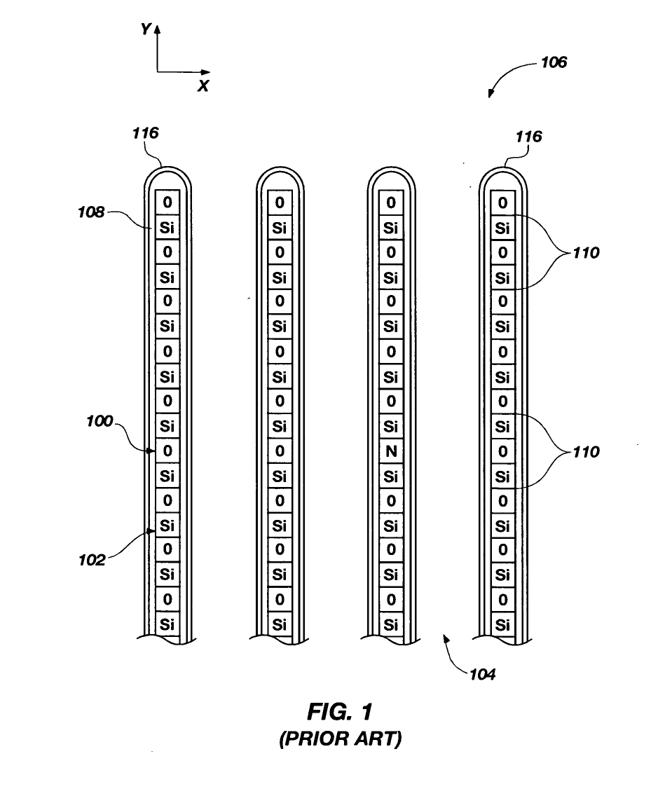

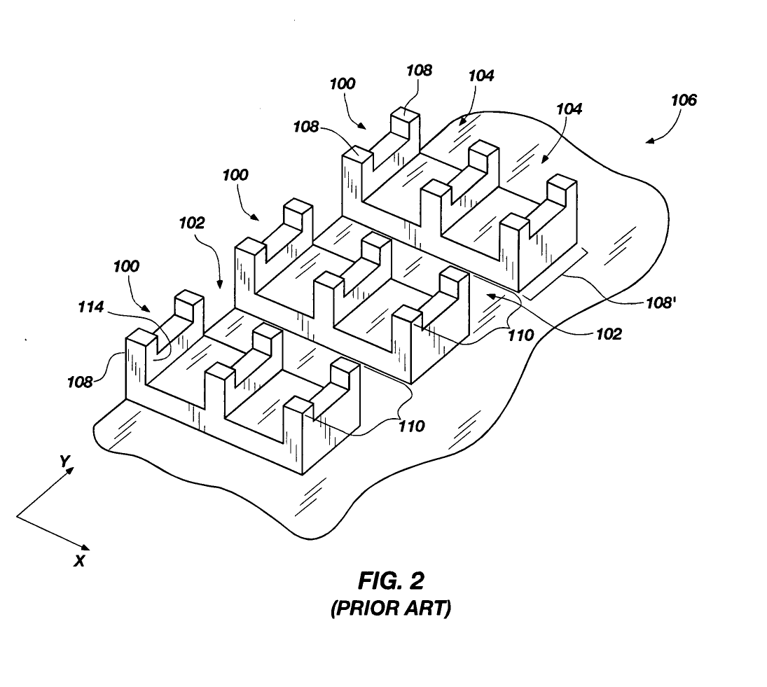

The method illustrated in FIGS. 3A-11E may provide a simplified process flow for forming the structures shown in FIGS. 1 and 2, since only a single photolithography act is used. The intermediate semiconductor device structure 200I (shown in FIGS. 11A-11E) may be subjected to further processing, as known in the art, to produce the structures shown in FIGS. 1 and 2. Inter alia, the spacers 208 may be removed using a wet etch or a dry etch that is selective for the material of the spacers 208 relative to the first and second fill materials 216, 224 and the unetched portions of the pattern layer 204″. For instance, the spacers 208 may be removed with a hot phosphoric acid etch. The first and second fill materials 216, 224 may be removed using hydrogen fluoride (“HF”). As previously described, the first, second, and third sets of trenches 210, 212, 220 define an array of vertically extending pillars that include vertical source/drain regions. A gate line is formed within at least a portion of the third set of trenches 220, where the gate line and the vertical source/drain regions form a plurality of transistors in which pairs of the source/drain regions are connected to one another through a transistor channel.

In another embodiment, spacers are formed over portions of mask layers, which are in contact with the pattern layer, as shown in FIGS. 12A-24F. As shown in FIGS. 12A and 12B, a third mask layer 302 and a fourth mask layer 304 may be formed over the pattern layer 204. FIG. 12A is a top view of the intermediate semiconductor device structure 300A and FIG. 12B is a cross-section of the intermediate semiconductor device structure 300A along the dashed line labeled A. The third mask layer 302 and the fourth mask layer 304 may be formed from different materials so that at least portions of the third mask layer 302 and the fourth mask layer 304 may be selectively etchable relative to one another and relative to other exposed materials. The materials of the third mask layer 302 and the fourth mask layer 304 may include, but are not limited to, amorphous carbon, silicon oxide, polysilicon, or silicon oxynitride. The materials used as the third mask layer 302 and the fourth mask layer 304 may be selected based upon the etch chemistries and process conditions to which these layers will be exposed. For the sake of example only, if the third mask layer 302 is formed from amorphous carbon, the fourth mask layer 304 may be formed from polysilicon or silicon oxynitride. Alternatively, if the third mask layer 302 is formed from silicon oxide, the fourth mask layer 304 may be formed from polysilicon. The third mask layer 302 and the fourth mask layer 304 may be deposited on the pattern layer 204 by conventional techniques.

A photoresist layer 306 may be formed over the third mask layer 302 and patterned, as known in the art. While FIGS. 12A-24F illustrate forming a 1 F pattern on a 6 F pitch, other layouts may be formed. The photoresist layer 306 may be formed from a suitable photoresist material, such as previously described. The pattern may be transferred to the third mask layer 302 and the fourth mask layer 304, as shown in FIGS. 13A and 13B, exposing a portion of the top surface of the pattern layer 204. FIG. 13A is a top view of the intermediate semiconductor device structure 300B and FIG. 12B is a cross-section of the intermediate semiconductor device structure 300B along the dashed line labeled A. The etch of the third mask layer 302 and the fourth mask layer 304 may form second openings 308. FIGS. 12A-24F show a single, second opening 308 for the sake of clarity. However, in actuality, the intermediate semiconductor device structures 300A-300F may include a plurality of second openings 308. The third mask layer 302 and the fourth mask layer 304 may be etched using an etch chemistry that removes portions of the third mask layer 302 and the fourth mask layer 304 simultaneously. Alternatively, the portions of the third mask layer 302 and the fourth mask layer 304 may be removed sequentially, using different etch chemistries. The etch chemistries used for the third mask layer 302 and the fourth mask layer 304 may also remove the photoresist layer 306. Alternatively, the photoresist layer 306 may be removed using a separate etch.

The third mask layer 302 may be further etched or “trimmed,” as shown in FIGS. 14A and 14B. FIG. 14A is a top view of the intermediate semiconductor device structure 300C and FIG. 14B is a cross-section of the intermediate semiconductor device structure 300C along the dashed line labeled A. The third mask layer 302 may be anisotropically etched so that portions of the third mask layer 302 are removed without substantially etching the fourth mask layer 304. As a consequence, the second openings 308 may have a first width W and a second width W′, where the second width W′ is greater than the first width W. The third mask layer 302 may be selectively etched using a wet etch chemistry as described in U.S. patent application Ser. No. 11/514,117, filed Aug. 30, 2006, entitled “SINGLE SPACER PROCESS FOR MULTIPLYING PITCH BY A FACTOR GREATER THAN TWO AND RELATED INTERMEDIATE IC STRUCTURES,” the disclosure of which is incorporated by reference herein in its entirety.

A spacer layer may then be formed over the exposed surfaces of the pattern layer 204, the third mask layer 302, and the fourth mask layer 304. As previously described, the spacer layer may be conformally deposited by conventional techniques. The spacer layer may be formed to a thickness that is approximately equal to the desired thickness of spacers to be formed therefrom. The spacer layer may be formed from a material that is selectively etchable relative to the materials used in the pattern layer 204, the third mask layer 302, and the fourth mask layer 304. For the sake of example only, the spacer layer may be formed from SiN or SiOₓ. Selection of the material used as the spacer layer may depend on the materials used as the third mask layer 302 and the fourth mask layer 304. If the third mask layer 302 and the fourth mask layer 304 are amorphous carbon and polysilicon, respectively, or amorphous carbon and SiON, respectively, the spacer layer may be formed from SiOₓ. If the third mask layer 302 and the fourth mask layer 304 are SiOₓ and polysilicon, respectively, the spacer layer may be formed from SiN. The spacer layer may be anisotropically etched, removing material from substantially horizontal surfaces while leaving the material on substantially vertical surfaces.

After the etch, spacers 208 formed from the spacer layer may remain on substantially vertical surfaces of the third mask layer 302 and spacers 208′ may remain on substantially vertical surfaces of the fourth mask layer 304. Substantially horizontal surfaces of the third mask layer 302 may be exposed, as are a portion of substantially horizontal surfaces of the fourth mask layer 304, as shown in FIGS. 15A and 15B. FIG. 15A is a top view of the intermediate semiconductor device structure 300D and FIG. 15B is a cross-section of the intermediate semiconductor device structure 300D along the dashed line labeled A. The anisotropic etch may be a plasma etch, such as a CF₄-containing plasma, a CHF₃-containing plasma, a CH₂F₂-containing plasma, or mixtures thereof. The spacers 208, 208′ extend longitudinally along both sides of the third mask layer 302 and along exposed portions of the fourth mask layer 304. The spacers 208, 208′ may reduce the first width W′ of the second openings 308, while substantially filling in the second width W. The width of the spacers 208, 208′ may correspond to the desired width of features ultimately to be formed on the intermediate semiconductor device structure 300D. For instance, the width of the spacers 208, 208′ may be 1 F.

A sixth mask layer 310 may be formed over the exposed surfaces of the spacers 208, 208′, the third mask layer 302, and the fourth mask layer 304. The sixth mask layer 310 may be formed from a photoresist material or amorphous carbon. Portions of the sixth mask layer 310 extending above the spacers 208, 208′ and the third mask layer 302 may be removed, such as by CMP, forming a substantially planar surface. As shown in FIGS. 16A and 16B, top surfaces of the spacers 208, 208′, the third mask layer 302, and the sixth mask layer 310 may be exposed. FIG. 16A is a top view of the intermediate semiconductor device structure 300E and FIG. 16B is a cross-section of the intermediate semiconductor device structure 300E along the dashed line labeled A. As described in detail below, a fourth set of trenches may be ultimately formed in the pattern layer 204 beneath the portions of the third mask layer 302 and a fifth set of trenches may be ultimately formed in the pattern layer 204 beneath portions of the fourth mask layer 304. The spacers 208, 208′ may prevent undesired portions of the fourth mask layer 304 and the pattern layer 204 from being etched. During various stages of processing, the third mask layer 302, the fourth mask layer 304, and the spacers 208, 208′ may function as masks to form the fourth set of trenches 312 and the fifth set of trenches 314 (shown in FIG. 19B) having different depths.

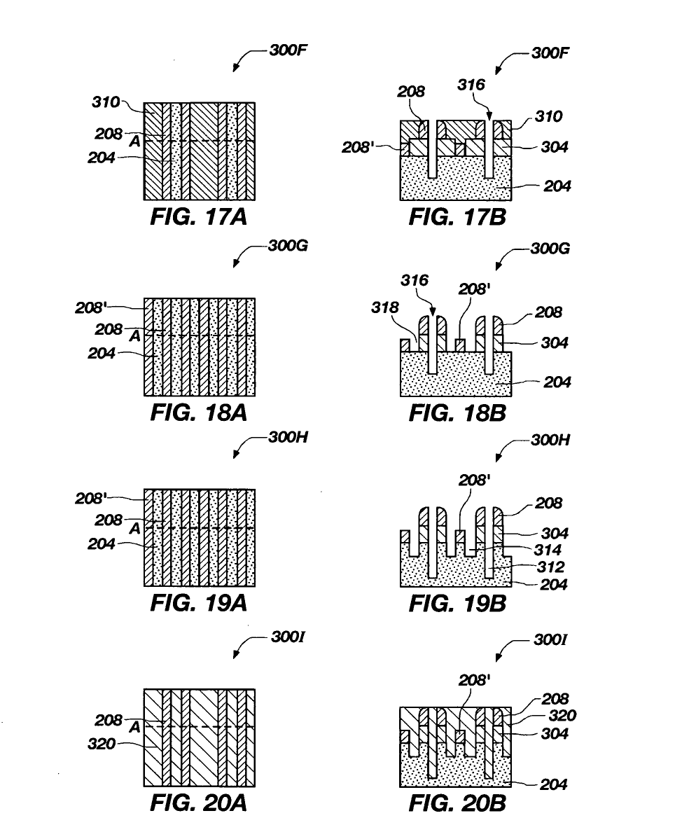

As shown in FIGS. 17A and 17B, the exposed third mask layer 302 and the underlying fourth mask layer 304 and the pattern layer 204 may be etched to form third openings 316, which will be further etched, as described below, to form the fourth set of trenches 312. FIG. 17A is a top view of the intermediate semiconductor device structure 300F and FIG. 17B is a cross-section of the intermediate semiconductor device structure 300F along the dashed line labeled A. Depending on the materials used, these layers may be etched sequentially or a single etch chemistry may be used to etch all three layers. The etch chemistry may be selected depending on the materials used. The sixth mask layer 310 may be removed, exposing portions of the fourth mask layer 304. As shown in FIGS. 18A and 18B, the exposed portions of the fourth mask layer 304 may be selectively etched relative to the spacers 208, 208′, forming fourth openings 318, which will be further etched, as described below, to form the fifth set of trenches 314. FIG. 18A is a top view of the intermediate semiconductor device structure 300G and FIG. 18B is a cross-section of the intermediate semiconductor device structure 300G along the dashed line labeled A.

The depths of the third and fourth openings 316, 318 may be increased by further etching the pattern layer 204, as shown in FIGS. 19A and 19B, forming the fourth set of trenches 312 and the fifth set of trenches 314. FIG. 19A is a top view of the intermediate semiconductor device structure 300H and FIG. 19B is a cross-section of the intermediate semiconductor device structure 300H along the dashed line labeled A. The exposed portions of the pattern layer 204 may be selectively etched relative to the spacers 208, 208′, maintaining the relative depths of the trenches in the fourth set of trenches 312 and the fifth set of trenches 314. In other words, the depth of the trenches in the fourth set of trenches 312 may remain deeper than the depth of the trenches in the fifth set of trenches 314. The trenches of the fourth set of trenches 312 may have a depth within a range of from approximately 1500 Å to approximately 3500 Å, such as from approximately 2150 Å to approximately 2250 Å. The trenches of the fifth set of trenches 314 may have a depth within a range of from approximately 300 Å to approximately 3000 Å, such as from approximately 950 Å to approximately 1050 Å.

A liner (not shown) may, optionally, be formed in the trenches of the fourth and fifth sets of trenches 312, 314, before filling the fourth and fifth sets of trenches 312, 314. The liner may be formed as described above. A third fill material 320, such as a dielectric material, may be deposited in the trenches of the fourth and fifth sets of trenches 312, 314 and over the spacers 208, 208′. The fourth and fifth sets of trenches 312, 314 may be filled substantially simultaneously. The third fill material 320 may be one of the materials previously described and may be deposited, densified, and planarized, as previously described. The third fill material 320 may be planarized such that top surfaces of the spacers 208, 208′ are exposed, as shown in FIGS. 20A and 20B. FIG. 20A is a top view of the intermediate semiconductor device structure 300I and FIG. 20B is a cross-section of the intermediate semiconductor device structure 300I along the dashed line labeled A.

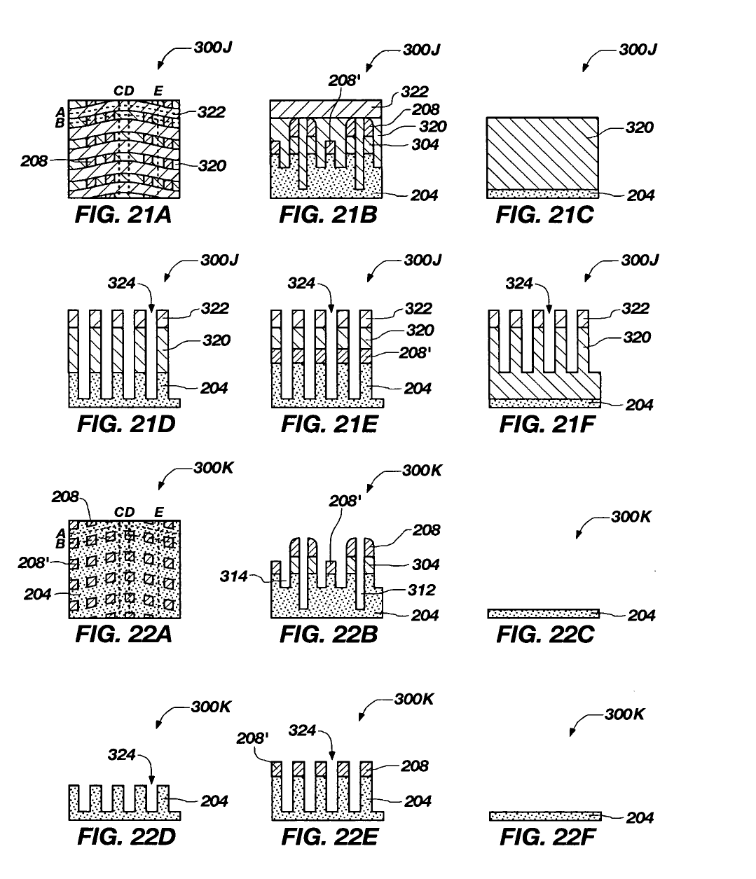

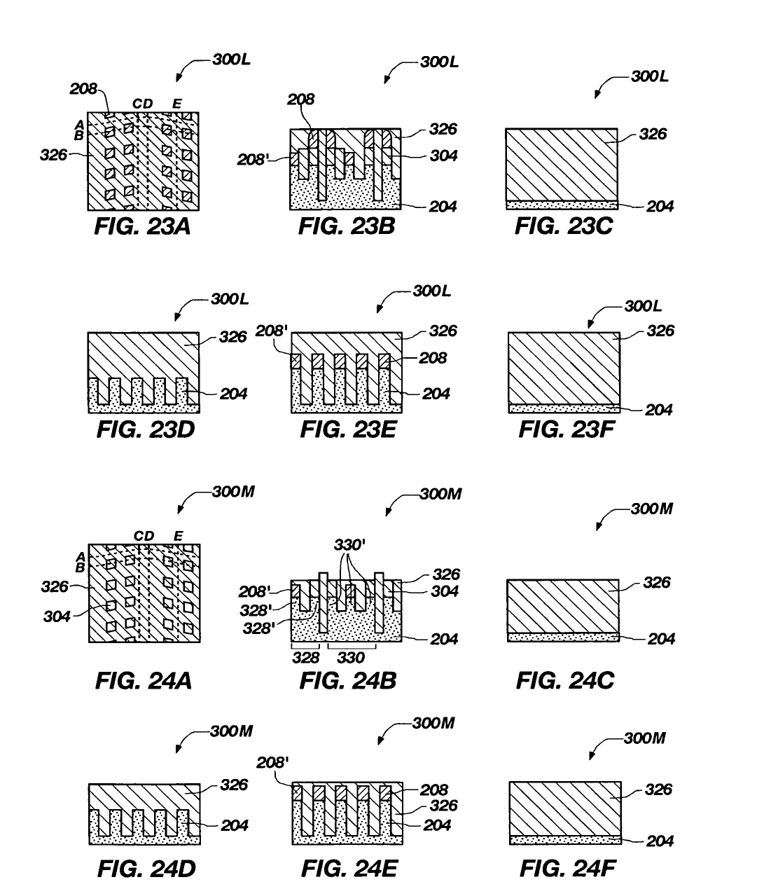

A sixth mask layer 322, such as a photoresist layer, may be formed over the top surfaces of the spacers 208, 208′ and the third fill material 320, as shown in FIGS. 21A-21F. FIG. 21A is a top view of the intermediate semiconductor device structure 300J, FIG. 21B is a cross-section of the intermediate semiconductor device structure 300J along the dashed line labeled A, FIG. 21C is a cross-section of the intermediate semiconductor device structure 300J along the dashed line labeled B, FIG. 21D is a cross-section of the intermediate semiconductor device structure 300J along the dashed line labeled C, FIG. 21E is a cross-section of the intermediate semiconductor device structure 300J along the dashed line labeled D, and FIG. 21F is a cross-section of the intermediate semiconductor device structure 300J along the dashed line labeled E. Using the sixth mask layer 322, a sixth set of trenches 324 may be formed in the pattern layer 204. The sixth set of trenches 324 may extend substantially laterally in the horizontal plane of the intermediate semiconductor device structure 300J. As such, the sixth set of trenches 324 may be oriented substantially perpendicular or orthogonal to the fourth and fifth sets of trenches 312, 314. The sixth set of trenches 324 may be formed as described above for the third set of trenches 220. The sixth mask layer 322 and, optionally, the third fill material 320 in the fourth and fifth sets of trenches 312, 314 may be removed, as shown in FIGS. 22A-22F. FIG. 22A is a top view of the intermediate semiconductor device structure 300K, FIG. 22B is a cross-section of the intermediate semiconductor device structure 300K along the dashed line labeled A, FIG. 22C is a cross-section of the intermediate semiconductor device structure 300K along the dashed line labeled B, FIG. 22D is a cross-section of the intermediate semiconductor device structure 300K along the dashed line labeled C, FIG. 22E is a cross-section of the intermediate semiconductor device structure 300K along the dashed line labeled D, and FIG. 22F is a cross-section of the intermediate semiconductor device structure 300K along the dashed line labeled E. Alternatively, at least portions of the third fill material 320 may remain in the fourth and fifth sets of trenches 312, 314 (not shown) to increase stability of the intermediate semiconductor device structure 300K. If the third fill material 320 in the fourth and fifth sets of trenches 312, 314 is substantially completely removed, the fourth and fifth sets of trenches 312, 314 may be re-filled with a fourth fill material 326, as shown in FIGS. 23A-23F. FIG. 23A is a top view of the intermediate semiconductor device structure 300L, FIG. 23B is a cross-section of the intermediate semiconductor device structure 300L along the dashed line labeled A, FIG. 23C is a cross-section of the intermediate semiconductor device structure 300L along the dashed line labeled B, FIG. 23D is a cross-section of the intermediate semiconductor device structure 300L along the dashed line labeled C, FIG. 23E is a cross-section of the intermediate semiconductor device structure 300L along the dashed line labeled D, and FIG. 23F is a cross-section of the intermediate semiconductor device structure 300L along the dashed line labeled E. The fourth fill material 326 may be one of the materials previously described and may be deposited, densified, and planarized, as previously described. The fourth fill material 326 may be planarized such that top surfaces of the spacers 208 are exposed.

The spacers 208 may be removed, along with portions of the fourth fill material 326, until a top surface of the fourth mask layer 304 is exposed, as shown in FIGS. 24A-24F. FIG. 24A is a top view of the intermediate semiconductor device structure 300M, FIG. 24B is a cross-section of the intermediate semiconductor device structure 300M along the dashed line labeled A, FIG. 24C is a cross-section of the intermediate semiconductor device structure 300M along the dashed line labeled B, FIG. 24D is a cross-section of the intermediate semiconductor device structure 300M along the dashed line labeled C, FIG. 24E is a cross-section of the intermediate semiconductor device structure 300M along the dashed line labeled D, and FIG. 24F is a cross-section of the intermediate semiconductor device structure 300M along the dashed line labeled E.

The intermediate semiconductor device structure 300M (shown in FIGS. 24A-24F) may be subjected to further processing, as known in the art, to produce a RAD DRAM. The remaining processing acts are known in the art and, therefore, are not described in detail herein. Inter alia, the remainder of the fourth fill material 326 may be removed, exposing the spacers 208′ and the fourth mask layer 304 and exposing the fourth and fifth sets of trenches 312, 314. The spacers 208′ and the fourth mask layer 304 may be selectively etched without substantially etching the exposed portions of the pattern layer 204. After further processing, the intermediate semiconductor device structure may include a pair of pillars 328 formed from the pattern layer 204 and an adjacent, triplet of pillars 330 formed from the pattern layer 204. Trenches in the fifth set of trenches 314 may separate each pillar 328′ in the pair of pillars 328 and each pillar 330′ in the triplet of pillars 330. The pair of pillars 328 may be separated from the triplet of pillars 330 by the trenches in the fourth set of trenches 312. The trenches in the fourth and fifth sets of trenches 312, 314 and the pillars 328′, 330′ may extend substantially longitudinally in the horizontal direction of the intermediate semiconductor device structure 300M. The fourth and fifth sets of trenches 312, 314 are shown filled with fourth fill material 326 in FIGS. 24A-24F.

Isolation regions may be formed in the trenches of the fourth set of trenches 312 and gates in the trenches of the fifth set of trenches 314. The sixth set of trenches 324 may be wordline trenches. The isolation regions and the gates may be formed by conventional techniques, which are not described in detail herein. Each of the exterior pillars 330′ in the triplet of pillars 330 may be connected to a capacitor while the interior, center pillar 330′ may be connected to a digit line or bit line.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention is to cover all modifications, equivalents, and alternatives falling within the spirit and scope of the invention as defined by the following appended claims.

1. A method of forming staggered heights in a pattern layer, comprising:
forming first openings in a pattern layer, wherein a first mask layer overlies portions of the pattern layer;
forming spacers adjacent to etched portions of the pattern layer to reduce a width of the first openings;
etching the pattern layer to increase a depth of the first openings; and forming second openings in the pattern layer.

2. The method of claim 1, wherein forming first openings in a pattern layer comprises forming first openings in a pattern layer comprising silicon.

3. The method of claim 1, wherein forming first openings in a pattern layer comprises forming first openings in a pattern layer comprising a semiconductor substrate.

4. The method of claim 1, wherein forming first openings in the pattern layer comprises forming the first openings in exposed portions of the pattern layer.

5. The method of claim 1, wherein etching the pattern layer to increase a depth of the first openings comprises forming the first openings to have a depth greater than the depth of the second openings.

6. The method of claim 1, wherein etching the pattern layer to increase a depth of the first openings comprises etching portions of the pattern layer positioned between adjacent pairs of spacers.

7. The method of claim 1, wherein etching the pattern layer to increase a depth of the first openings comprises increasing the depth of the first openings to isolate adjacent semiconductor devices in the pattern layer.

8. The method of claim 1, wherein forming second openings in the pattern layer comprises forming the second openings while the first openings remain substantially unfilled.

9. The method of claim 1, wherein forming second openings in the pattern layer comprises forming the second openings in portions of the pattern layer positioned between a pair of spacers.

10. The method of claim 1, wherein forming second openings in the pattern layer comprises forming the second openings in the pattern layer underlying the first mask layer.

11. The method of claim 1, wherein forming first openings in the pattern layer and forming second openings in the pattern layer comprises forming the first openings and the second opening using a single photolithography act.

12. The method of claim 1, wherein forming spacers adjacent to etched portions of the pattern layer to reduce a width of the first openings comprise conducting two or more spacer etch processes.

13. The method of claim 1, further comprising substantially simultaneously filling the first openings and the second openings with a dielectric material.

14-27. (canceled)

28. A method of forming staggered heights in a pattern layer, comprising:
removing portions of a pattern layer to form a plurality of openings therein, each opening of the plurality of openings defined by sidewalls;
forming spacers on the sidewalk of each opening of the plurality of openings; and
removing portions of the pattern layer exposed between the spacers to form a plurality of trenches, the plurality of trenches having different depths.

29. The method of claim 28, wherein removing portions of the pattern layer exposed between the spacers to form a plurality of trenches comprises increasing the depth of the plurality of openings to form a first set of trenches and removing additional portions of the pattern layer to form a second set of trenches.

30. The method of claim 29, wherein forming a first set of trenches and a second set of trenches comprises forming the second set of trenches having a shallower depth than the first set of trenches.

31. The method of claim 29, wherein forming a first set of trenches comprises forming the first set of trenches having a sufficient depth to isolate adjacent semiconductor devices.

32. The method of claim 29, wherein forming a first set of trenches and a second set of trenches comprises forming the first set of trenches and the second set of trenches using a single photo lithography act.

33. A method of forming staggered heights in a pattern layer, comprising:
removing at least a portion of a pattern layer to form protrusions therein;
forming spacers adjacent to the protrusions;
removing the protrusions and a portion of the pattern layer underlying the protrusions to form a first set of trenches in the pattern layer; and
removing exposed portions of the pattern layer between adjacent protrusions to form a second set of trenches in the pattern layer.

34. The method of claim 33, wherein forming a second set of trenches in the pattern layer comprises forming each trench of the second set of trenches to have a depth substantially less than each trench of the first set of trenches.

35. The method of claim 33, wherein forming a first set of trenches in the pattern layer and forming a second set of trenches in the pattern layer comprises forming the first set of trenches and the second set of trenches using a single etching act.

36. A method of forming staggered heights in a pattern layer, comprising:
removing exposed portions of a pattern layer to form a plurality of openings therein;
forming spacers on sidewalls of the plurality of openings;
removing portions of the pattern layer exposed between the spacers to form pairs of pillars therein.

37. The method of claim 36, wherein removing portions of the pattern layer exposed between the spacers to form pairs of pillars therein comprises separating each pair of pillars from an adjacent pair of pillars by a first set of trenches.

38. The method of claim 37, wherein removing portions of the pattern layer exposed between the spacers to form pairs of pillars therein comprises separating each pillar of the pair of pillars by a second set of trenches.

39. The method of claim 38, wherein the first set of trench is deeper than the second set of trenches.
